(19) United States
(12) Patent Application Publication
(10) Pub. No.: US 2008/0003822 A1
(43) Pub. Date: Jan. 3, 2008

(54) Method for fabricating semiconductor device

(75) Inventors: Ki-Won Nam, Kyoungki-do (KR); Ju-Hee Hwang, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/805,105

(22) Filed: May 22, 2007

(30) Foreign Application Priority Data
Jun. 29, 2006 (KR) 2006-0059327

(51) Int. Cl. H01L 21/44

(52) U.S. Cl. 438/672; 257/E21.476

(57) ABSTRACT

A method for fabricating a semiconductor device includes forming an insulation pattern including an open region over a substrate, forming a polysilicon layer over the insulation pattern, the open region, and the substrate, performing an etch-back process on the polysilicon layer to form a plug, and removing polymers generated during the etch-back process using a gas mixture including a first gas comprising a fluorine functional group and a second gas comprising an oxygen functional group.

### CROSS-REFERENCE TO RELATED APPLICATIONS

The present invention claims priority of Korean patent application number 10-2006-0059327, filed on Jun. 29, 2006, which is incorporated by reference in its entirety.

### BACKGROUND OF THE INVENTION

The present invention relates to a method for fabricating a semiconductor device, and more particularly, to a method for fabricating a semiconductor device, which can remove polymers remaining over a wafer after performing an etch-back process on a polysilicon layer to form plugs.

Storage node contact plugs have been typically used to maintain a contact process margin of storage nodes when fabricating dynamic random access memories (DRAM). Polysilicon has been used as a typical plug material. A typical method for forming a plug includes selectively etching an insulation layer (an oxide-based layer and/or a nitride-based layer) to form an open region for forming a plug, forming a polysilicon layer over the resultant structure, and performing an etch-back process on the polysilicon layer.

If a large height difference occurs between the plug and the insulation layer after performing the etch-back process, the large height difference may become a source for failure during a subsequent process. Thus, the etch-back process includes performing a dry etch process with selectivity between the polysilicon layer and the insulation layer substantially being approximately 1:1. That is, the etch-back process is performed in a manner that the insulation layer and the polysilicon layer are etched at substantially the same rate and thus planarization may be achieved.

However, a certain etch-back condition that generates a large amount of polymers is often required to have the etch rates of the insulation layer and the polysilicon layer to be substantially the same and achieve planarization. Thus, a cleaning process is generally needed to remove the polymers before performing a subsequent process.

FIGS. 1 and 2 illustrate a polysilicon plug formed as a storage node contact plug in a 90 nm technology DRAM fabrication process.

FIG. 1 illustrates a micrographic map showing an appearance of polymer-based particles remaining over a surface of a wafer after an etch-back process is performed on a polysilicon layer. A large amount of polymers remain on the surface of the wafer and generate undesirable formations as represented with reference denotation ‘A’. Such polymers remain over the wafer after etching is performed. The polymers are hard type polymers which are often not completely removed by a cleaning process.

FIG. 2 illustrates micrographic views showing appearances of the polymers after the etch-back process is performed on the polysilicon layer. An undesirable event showing an appearance of polymers is illustrated with reference denotation ‘B’. The polymers ‘B’ remain on the polysilicon plug and the wafer.

The aforementioned polymers generally include a carbon-based material. The polymers may become a particle source during a subsequent process such as patterning and cause undesirable events during the subsequent process.

### SUMMARY OF THE INVENTION

Embodiments of the present invention are directed to provide a method for fabricating a semiconductor device, which can remove polymers remaining over a wafer after an etch-back process is performed.

In accordance with an aspect of the present invention, there is provided a method for fabricating a semiconductor device, including: forming an insulation pattern including an open region over a substrate; forming a polysilicon layer over the insulation pattern, the open region, and the substrate; performing an etch-back process on the polysilicon layer to form a plug; and removing polymers generated during the etch-back process using a gas mixture including a first gas comprising a fluorine functional group and a second gas comprising an oxygen functional group.

### BRIEF DESCRIPTION OF THE DRAWINGS

FIG. 1 illustrates a micrographic map showing typical polymer-based particles remaining over a surface of a wafer after an etch-back process is performed on a polysilicon layer.

FIG. 2 illustrates micrographic views showing typical appearances of polymers after an etch-back process is performed on a polysilicon layer.

FIGS. 3A and 3B illustrate cross-sectional views of a method for fabricating a semiconductor device in accordance with an embodiment of the present invention.

FIG. 4 illustrates a micrographic map showing polymer particles after an etch-back process and a post treatment are performed in accordance with the embodiment of the present invention.

FIG. 5 illustrates a micrographic view showing appearances of polymers after an etch-back process and a post treatment are performed in accordance with the embodiment of the present invention.

### DESCRIPTION OF SPECIFIC EMBODIMENTS

Embodiments of the present invention relate to a method for fabricating a semiconductor device. According to an embodiment of the present invention, an undesirable event in a subsequent process may be reduced by removing hard polymers. Furthermore, processes may be simplified because polymers are removed by performing a post treatment in an apparatus in which an etch-back process is previously performed. Thus, a yield and productivity may improve.

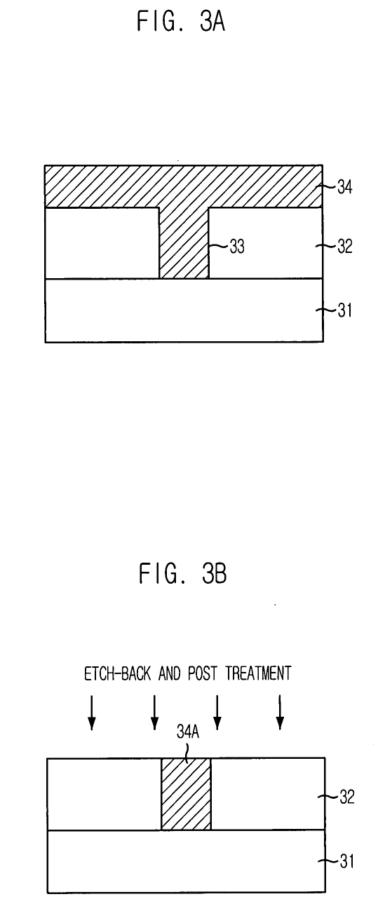

FIGS. 3A and 3B illustrate cross-sectional views of a method for fabricating a semiconductor device in accordance with an embodiment of the present invention.

Referring to FIG. 3A, an insulation layer 32 including an open region 33 is formed over a substrate 31. In a dynamic random access memory (DRAM) for instance, the substrate 31 includes isolation structures, word lines, and bit lines generally needed to configure the DRAM. The insulation layer 32 may include an oxide-based layer, a nitride-based layer, or a stack structure configured with an oxide-based layer and a nitride-based layer. Also, the insulation layer 32 may function as an inter-layer insulation layer and/or an etch stop layer. The open region 33 is formed using a mask and an etch process. A plug will be formed over the open region 33.

The substrate 31 exposed by the open region 33 may include a conductive layer or a silicon bulk layer. A polysilicon layer 34 is formed over the resultant structure. The polysilicon layer 34 is formed under certain conditions and in a certain thickness such that the polysilicon layer 34 sufficiently fills the open region 33 without generating voids.

Referring to FIG. 3B, an etch-back process is performed on the polysilicon layer 34 until the insulation layer 32 is exposed. The etch-back process may include performing a dry etch process with selectivity between the polysilicon layer 34 and the insulation layer 32 substantially being approximately 1:1 to achieve planarization. Furthermore, the etch-back process may includes performing a number of processes. A first process includes increasing an etch rate of the polysilicon layer 34 until just before the insulation layer 32 is exposed. A second process includes maintaining the etch rate of the polysilicon layer 34 and the insulation layer 32 to be substantially the same. The second process may be an over etch process. A polysilicon plug 34A is formed over the open region 33 after the etch-back process is performed.

A large amount of polymer-based particles are typically generated on the surface of the wafer after the aforementioned etch-back process is performed. In this embodiment of the present invention, polymers are removed using a gas mixture including a gas comprising a fluorine functional group and another gas comprising an oxygen functional group.

The gas comprising the fluorine functional group may include tetrafluoromethane (CF₄) or fluoroform (CHF₃). The gas comprising the oxygen functional group may include oxygen (O₂). The oxygen functional group oxidizes the polymers and the fluorine functional group removes the oxidized polymers with ease. Flow rates of the gas comprising the fluorine functional group and the gas comprising the oxygen functional group may be substantially the same. Over etch may occur when a larger amount of a fluorine-based gas is supplied than an oxygen-based gas. Also, an amount of oxidized polymers may become larger than an amount of etched polymers when a larger amount of the oxygen-based gas is supplied than the fluorine-based gas.

The polymers may be removed in an apparatus in-situ by performing a post treatment, wherein the apparatus is the same apparatus in which the etch-back process is previously performed. Although a flow rate of the aforementioned gas mixture may change according to the previous processes, that is, according to the level of polymer generation, the flow rate of the gas mixture may range from approximately 50 sccm to approximately 300 sccm. A low chamber pressure ranging from approximately 1 mT to approximately 10 mT is used to remove the polymers more effectively. A polymer removal characteristic may deteriorate if the pressure increases or decreases from the range.

Meanwhile, a plasma source for generating ions after supplying the gas mixture may include microwave. Using the microwave may remove the polymers and reduce damage on the insulation layer 32. A power of the microwave may range from approximately 300 W to approximately 1,200 W.

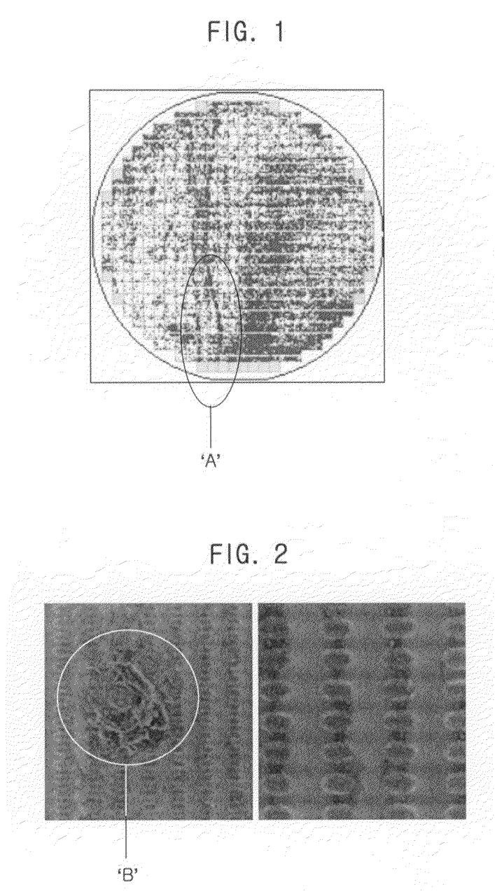

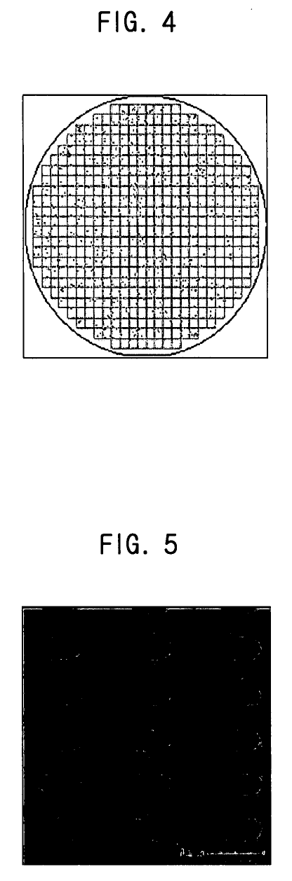

FIG. 4 illustrates a micrographic map showing polymer particles after an etch-back process and a post treatment are performed in accordance with the embodiment of the present invention. Polymers remaining on a wafer are substantially removed and there are much less undesirably formed chips when compared with the wafer shown in FIG. 1.

FIG. 5 illustrates a micrographic view showing a polysilicon plug after an etch-back process and a post treatment are performed in accordance with the embodiment of the present invention. Polymers are better removed when compared with the wafer shown in FIG. 2.

According to the embodiment of the present invention, the embodiment may be usefully applied in a storage node contact plug formation process in a DRAM fabrication. The embodiment may also be applied in other processes such as a polysilicon landing plug formation process and a polysilicon line formation process using a damascene process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an insulation pattern including an open region over a substrate;
forming a polysilicon layer over the insulation pattern, the open region, and the substrate;
performing an etch-back process on the polysilicon layer to form a plug; and
removing polymers generated during the etch-back process using a gas mixture including a first gas comprising a fluorine functional group and a second gas comprising an oxygen functional group.

2. The method of claim 1, wherein said removing the polymers comprises performing a post treatment in an apparatus in which the etch-back process is performed.

3. The method of claim 1, wherein said performing the etch-back process comprises performing a dry etch process with selectivity between the polysilicon layer and the insulation pattern being approximately 1:1.

4. The method of claim 1, wherein the gas mixture comprises the first gas and the second gas flowing at substantially the same rate during the etch-back process.

5. The method of claim 1, wherein the polymers are removed by plasma-ionizing the gas mixture using microwave.

6. The method of claim 1, wherein the first gas comprises one of tetrafluoromethane (CF₄) and fluoroform (CHF₃).

7. The method of claim 1, wherein the second gas comprises oxygen (O₂).

8. The method of claim 1, wherein said removing the polymers comprises using a pressure ranging from approximately 1 mT to approximately 10 mT in a chamber.

9. The method of claim 5, wherein the gas mixture flows at a rate ranging from approximately 50 sccm to approximately 300 sccm.

10. The method of claim 5, wherein a power of the microwave ranges from approximately 300 W to approximately 1,200 W.

11. The method of claim 1, wherein the plug comprises one of a landing plug and a storage node contact plug in a memory device.

12. The method of claim 1, wherein the insulation pattern comprises one of an oxide-based layer and a nitride-based layer.
